(19) United States
(12) Patent Application Publication
(10) Pub. No.: US 2026/0264192 A1
(43) Pub. Date: Sep. 10, 2026

(54) POLISHING PAD AND POLISHING METHOD FOR SEMICONDUCTOR WAFER

(71) Applicant: NORITAKE CO., LIMITED, Nagoya-shi, Aichi (JP)

(72) Inventors: Makoto SATO, Nagoya-shi (JP); Shota KITAJIMA, Nagoya-shi (JP); Hisanori KUROBE, Nagoya-shi (JP); Masatoshi KISHIMOTO, Nagoya-shi (JP)

(73) Assignees: NORITAKE CO., LIMIED, Nagoya-shi, Aichi (JP); NORITAKE CO., LIMITED, Nagoya-shi, Aichi (JP)

(21) Appl. No.: 19/162,757

(22) PCT Filed: Mar. 4, 2024
(86) PCT No.: PCT/JP2024/008145

§ 371 Date: Sep. 5, 2025

(30) Foreign Application Priority Data
Mar. 4, 2024 (JP) 2023-034103

(51) Int. Cl. B24B 37/24; H10P 52/40

(52) U.S. Cl. CPC B24B 37/24; H10P 52/402

(57) ABSTRACT

A polishing pad for polishing a semiconductor wafer by using a polishing fluid that is a strong oxidizing agent solution containing no abrasive grain. The polishing pad is made of a polymer containing carbon C and at least one of hydrogen H, oxygen O, nitrogen N, sulfur S and fluorine F, and has a polishing-rate contribution degree PRN expressed by formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), such that the polishing-rate contribution degree PRN satisfies formula (2).

$$PRN = - 5738 {M}_{H} + 84 9.6 {M}_{C} + 1766 {M}_{O} - 40.7 {M}_{N} - 39 4.9 {M}_{S} + 219.4 {M}_{F} \qquad ( 1 )$$

$$268.4 ≦ PRN ≦ 1516.3 \qquad ( 2 )$$

The present invention relates to a polishing pad and a polishing method for a semiconductor wafer, particularly, for a wafer that is difficult to polish, such as SiC, GaN and InP.

### BACKGROUND ART

Semiconductor wafers such as SiC wafer, GaN wafer, Si wafer and Si oxide wafer are known to be difficult to polish. Conventionally, such semiconductor wafers have been polished on a polishing table using a resin polishing pad with polishing abrasive grains being fixed to the pad, as in CMP (chemical mechanical polishing) method disclosed in Patent Document 1, for example. In such a polishing method with the abrasive grains, foreign matters in a polishing slurry are usually removed by passing the polishing slurry through a foreign-matter removal filter in a process of circulation of the polishing slurry, and the polishing slurry after the foreign matter removal is then supplied to the polishing table again.

In the conventional polishing method described above, if a filter with a very fine mesh is used to remove the abrasive grains from the polishing slurry, the filter becomes clogged and cannot be used, and if a filter with a slightly larger mesh is used instead, the filter's removal ability is insufficient, and the abrasive grains remaining in the polishing slurry can cause scratches on a polished surface of the semiconductor wafer. Further, the abrasive grains remaining in the polishing slurry have a higher specific gravity than a dispersion liquid and tend to settle and agglomerate in storage tank or transport pipeline, so that where the agglomerated abrasive grains flow onto the polishing pad, the abrasive grains tend to become unevenly dispersed on the polishing pad, thereby causing uneven polishing on the polished surface of the wafer.

On the other hand, a polishing method using a resin polishing pad and a chemical liquid has been proposed. Patent Document 2 discloses an example such as a polishing method.

### PRIOR ART DOCUMENTS

### Patent Documents

### Patent Document 1:

Japanese Unexamined Patent Application Publication No. 2013-214784

### Patent Document 2:

Japanese Unexamined Patent Application Publication No. 2021-057368

### SUMMARY OF THE INVENTION

### Object to be Achieved by the Invention

However, a polishing rate varies depending on type of a resin constituting a polishing pad, resulting in unstable polishing and lack of practicality.

The present invention was made in view of the background discussed above. It is therefore an object of the present invention to provide a polishing pad and a polishing method for a semiconductor wafer, which are capable of stably polishing the semiconductor wafer by using a resin polishing pad and a chemical liquid.

In view of the background discussed above, the present inventors conducted various studies to find out which resin components are effective in improving the polishing rate of semiconductor wafers. First, they used a resin constituted by element or elements such as carbon, hydrogen, oxygen, nitrogen, sulfur and fluorine as a resin plate (polishing table), so as to conduct tests for polishing wafers difficult to polish, such as SiC and GaN while supplying a potassium permanganate (KMnO₄) liquid as a strong oxidizing agent. Then, they made a regression analysis on contribution of each element to the polishing rate. As a result, they found that oxygen, carbon and fluorine tend to increase the polishing rate, and that nitrogen, sulfur and hydrogen tend to reduce the polishing rate. Based on the above facts, they defined a polishing-rate contribution degree, which is a sum of contents of respective elements multiplied by respective coefficients obtained in the regression analysis, and which is expressed by formula (1) described below. Then, they found that a high polishing rate can be obtained by using a resin with a composition ratio of carbon, hydrogen, oxygen, nitrogen, sulfur and fluorine, wherein the composition ratio causes the polishing-rate contribution degree expressed by the formula (1) to satisfy formula (2) described below in the resin. Further, they found that the polishing rate can be further improved by using an abrasive-containing polishing pad constituted by this resin. The present invention was obtained based on this knowledge.

### Measures for Solving the Problem

A gist of a polishing pad according to the present invention is that the polishing pad is made of a resin and is for polishing a semiconductor wafer by using a polishing fluid that is a strong oxidizing agent solution containing no abrasive grain, wherein the polishing pad is made of a polymer containing carbon C and at least one of hydrogen H, oxygen O, nitrogen N, sulfur S and fluorine F, and having a polishing-rate contribution degree PRN expressed by formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), such that the polishing-rate contribution degree PRN satisfies formula (2).

$$PRN = - 5738 {M}_{H} + 84 9.6 {M}_{C} + 1766 {M}_{O} - 40.7 {M}_{N} - 39 4.9 {M}_{S} + 219.4 {M}_{F} \qquad ( 1 )$$

$$268.4 ≦ PRN ≦ 1516.3 \qquad ( 2 )$$

Further, a gist of a polishing method according to the present invention is that the polishing method of polishing a semiconductor wafer by using a polishing fluid that is a strong oxidizing agent solution containing no abrasive grain, and a polishing pad made of a resin, wherein the polishing pad is made of a polymer containing carbon C and at least one of hydrogen H, oxygen O, nitrogen N, sulfur S and fluorine F, and having a polishing-rate contribution degree PRN expressed by formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), such that the polishing-rate contribution degree PRN satisfies formula (2).

### Effects of the Invention

In the polishing pad and the polishing method for polishing the semiconductor wafer according the present invention, the polishing fluid that is the strong oxidizing agent solution containing no abrasive grain, so that a fine-mesh filter can be used in a circulation path for circulating the polishing fluid, thereby making it possible to significantly reduce occurrence of scratches and to provide stable polishing of the semiconductor wafer, while suppressing consumption of the abrasive grains and reducing an environmental burden. In addition, the resin polishing pad is the polymer that contains the carbon and at least one of the hydrogen, oxygen, nitrogen, sulfur and fluorine, and the polishing-rate contribution degree PRN of the polishing pad is not lower than 268.4 and is not higher than 1516.3, so that the polishing rate is significantly improved.

Preferably, the polishing-rate contribution degree PRN of the polishing pad satisfies formula (3), so that the polishing-rate contribution degree PRN is not lower than 268.4 and is not higher than 959.3, whereby the polishing rate is further improved.

$$268.4 ≦ PRN ≦ 959. 3 \qquad ( 3 )$$

Preferably, the polishing fluid contains a potassium permanganate solution as the strong oxidizing agent solution. Thus, a reduction of potassium permanganate ions contained in the potassium permanganate solution is suppressed by the polymer constituting the polishing pad, thereby causing permanganate to precipitate on the polishing pad, and precipitated particles of the permanganate are used as abrasive particles to polish the semiconductor wafer.

Preferably, the resin constituting the polishing pad is one of PES (polyether sulfone) resin, PSU (polysulfone) resin, PPSU (polyphenyl sulfone) resin, PEEK (polyether ether ketone) resin, PU (polyurethane) resin, PET (polyethylene terephthalate (polyester)) resin, EP (epoxy) resin cured product (cured product of glycidyl ether type epoxy and amine hardener), PEG #400 acrylic resin (acrylic resin made by UV hardening an acrylate monomer in which acrylic groups are bonded to both ends of polyethylene glycol with an average molecular weight of 400), PC (polycarbonate) resin, PVDF80%+HFP20% (copolymer resin made of 80% polyvinylidene fluoride and 20% hexafluoropropylene) and PVDF100% (polyvinylidene fluoride resin). Thus, when the polishing fluid containing metal ions comes into contact with the polishing pad, metal oxide particles are deposited on the polishing pad.

Preferably, the polishing pad may have no abrasive grain and no independent pore or no communication pore, or may have the abrasive grains, independent pores and/or communication pores. Further, preferably, the polishing pad may contain silica abrasive grains, alumina abrasive grains, zirconia abrasive grains, manganese oxide abrasive grains and/or ceria abrasive grains as the abrasive grains in the independent pores and/or communication pores. Thus, it is easier to polish the semiconductor wafer to a flat surface owing to ubiquitous distribution of the abrasive grains, and to increases the number of points of action, thereby resulting in a high polishing rate.

Further, preferably, the gist of the polishing method using the polishing pad is that the polishing method of polishing the semiconductor wafer by using the polishing fluid that is the strong oxidizing agent solution containing no abrasive grain, and the polishing pad made of the resin, wherein the polishing pad is made of the polymer containing carbon C and at least one of hydrogen H, oxygen O, nitrogen N, sulfur S and fluorine F, and having a polishing-rate contribution degree PRN expressed by the formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), such that the polishing-rate contribution degree PRN satisfies the formula (2).

Thus, the polishing fluid that is the strong oxidizing agent solution containing no abrasive grains is used, so that a fine-mesh filter can be used in a circulation path for circulating the polishing fluid, thereby making it possible to significantly reduce occurrence of scratches and to provide stable polishing of the semiconductor wafer, while suppressing consumption of the abrasive grains and reducing an environmental burden. In addition, the resin polishing pad is the polymer that contains the carbon and at least one of the hydrogen, oxygen, nitrogen, sulfur and fluorine, and the polishing-rate contribution degree PRN of the polishing pad is not lower than 268.4 and is not higher than 1516.3, so that the polishing rate is significantly improved.

### BRIEF DESCRIPTION OF DRAWINGS

FIG. 1 A perspective view schematically showing a polishing machine that is to be used for a polishing operation in accordance with CMP method using a polishing plate according to an embodiment of the present invention.

FIG. 2 A plan view schematically showing a rotation mechanism for a holding disc of a polishing machine shown in FIG. 1.

FIG. 3 A view showing a chemical structural formula of PES resin (polyethersulfone resin) as an example of a resin constituting the polishing pad shown in FIG. 1.

FIG. 4 A view showing a chemical structural formula of PSU resin (polysulfone resin) as an example of the resin constituting the polishing pad shown in FIG. 1.

FIG. 5 A view showing a chemical structural formula of PPSU resin (polyphenylsulfone resin) as an example of the resin constituting the polishing pad shown in FIG. 1.

FIG. 6 A view showing a chemical structural formula of PEEK resin (polyetheretherketone resin) as an example of the resin constituting the polishing pad shown in FIG. 1.

FIG. 7 A view showing a chemical structural formula of PU resin (polyurethane resin synthesized from isocyanate and polyol) as an example of the resin constituting the polishing pad shown in FIG. 1.

FIG. 8 A view showing a chemical structural formula of PET resin (polyethylene terephthalate (polyester) resin) as an example of the resin constituting the polishing pad shown in FIG. 1.

FIG. 9 A view showing a chemical structural formula of EP resin (cured product of epoxy resin) as an example of the resin constituting the polishing pad shown in FIG. 1.

FIG. 10 A view showing a chemical structural formula of PEG #400 acrylic resin as an example of the resin constituting the polishing pad shown in FIG. 1.

FIG. 11 A view showing a chemical structural formula of PC resin (polycarbonate resin) as an example of the resin constituting the polishing pad shown in FIG. 1, and schematically showing a network structure of epoxy resin.

FIG. 12 A view showing a chemical structural formula of copolymer resin of 80% polyvinylidene fluoride and 20% hexafluoropropylene (PVDF (80%)-HFP (20%) resin) as an example of the resin constituting the polishing pad shown in FIG. 1.

FIG. 13 A view showing a chemical structural formula of PVDF (polyvinylidene fluoride resin) as an example of the resin constituting the polishing pad shown in FIG. 1.

FIG. 14 A view showing a chemical structural formula of melamine resin (thermoset) as a comparative example of the resin constituting the polishing pad shown in FIG. 1.

FIG. 15 A view showing a chemical structural formula of PA6 (polyamide 6 resin) as a comparative example of the resin constituting the polishing pad shown in FIG. 1.

FIG. 16 A view showing a chemical structural formula of PPS resin (linear type polyphenylene sulfide resin) as a comparative example of the resin constituting the polishing pad shown in FIG. 1.

FIG. 17 A table showing the resins of the polishing pads used for polishing SiC in Experimental Example 1, coefficients of elements composing each of the resins (obtained in regression analyses), a polishing rate, a surface roughness and a polishing-rate contribution degree.

FIG. 18 A view showing the polishing-rate contribution degree and the actual polishing rate in each of the resins of the polishing pads used for the examples 1-11 and comparative examples 1-3 in the Experimental Example 1.

FIG. 19 A view showing a polymer structure, which contains only carbon C and oxygen O with a higher proportion of the oxygen O, and which is theoretically considered to be able to maximize the polishing-rate contribution degree PRN.

FIG. 20 A view showing a paste-like precipitate adhered to a polishing surface of the polishing pad, by using an SEM photograph taken with a scanning electron microscope.

FIG. 21 A view showing an X-ray diffraction pattern obtained by X-ray diffraction of particulate matters shown in the SEM photograph of FIG. 20, as compared with the X-ray diffraction pattern of potassium permanganate.

FIG. 22 A table showing the resin, polishing rate and surface roughness in each of cases of polishing of SiC with the respective polishing pads in Experimental Example 2.

FIG. 23 A view schematically showing a structure of an abrasive-containing polishing pad as one of the polishing pads in the Experimental Example 2.

FIG. 24 A view schematically showing a polishing mechanism of the abrasive-containing polishing pad LHA (registered trademark).

FIG. 25 A table showing the resin, polishing rate and surface roughness in each of cases of polishing of SiC with the respective polishing pads in Experimental Example 3.

FIG. 26 A table showing the resin, polishing rate and surface roughness in each of cases of polishing of SiC with the respective polishing pads in Experimental Example 4.

### MODE FOR CARRYING OUT THE INVENTION

Hereinafter, there will be described an embodiment of the present invention, in detail with reference to the drawings. It is noted that figures of the drawings are simplified or deformed as needed, and each portion is not necessarily precisely depicted in terms of dimension ratio, shape, etc.

### Embodiment

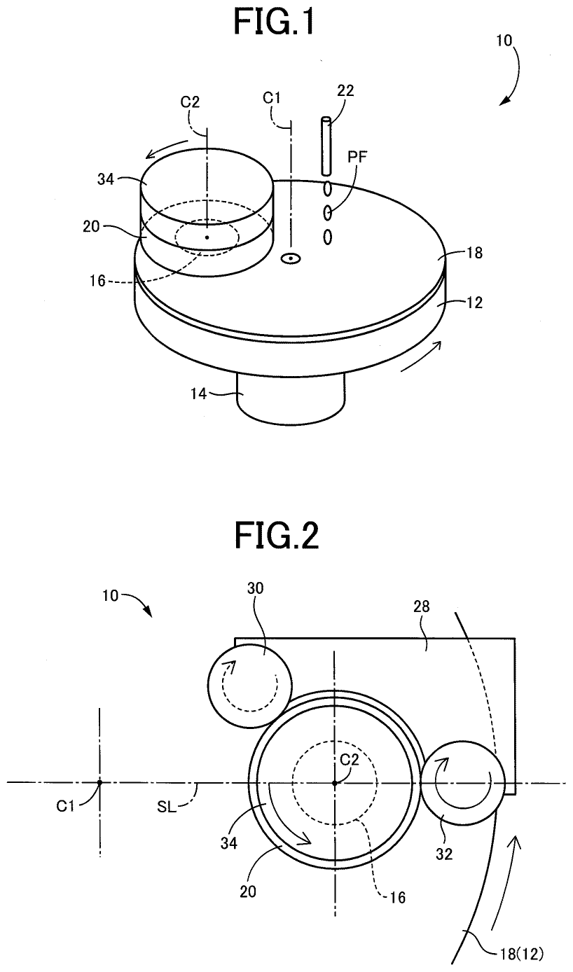

FIG. 1 conceptually shows main parts of a flat-surface polishing machine 10 as an example of the present invention, for polishing a compound semiconductor wafer such as SiC wafer, GaN wafer and InP wafer, with a guide-roller holder base being removed. In FIG. 1, the flat-surface polishing machine 10 is provided with a circular-shaped polishing table (rotary table) 12 supported so as to be rotatable about a rotation axis C1 that is perpendicular to the polishing table 12, and the polishing plate 12 is driven and rotated by a table drive motor 14 at a constant speed in one direction indicated by an arrow in FIG. 1. A sheet-shaped polishing pad 18, which is made of a resin, is attached to an upper surface of the polishing table 12, i.e., a surface against which a workpiece (semiconductor wafer) 16 is pressed.

The workpiece 16 is held on a lower surface of a holding disc 20, i.e., a surface of the holding disc 20 opposed to the polishing pad 18, and the holding disc 20 presses the workpiece 16 against the polishing pad 18 with a predetermined load. Further, a dripping nozzle 22 is provided in vicinity of the holding disc 20 of the flat-surface polishing machine 10, and a polishing fluid (lubricant) PF is supplied onto the polishing plate 12 from a tank (not shown).

The flat-surface polishing machine 10 is provided with an adjustment-tool holding member (not shown) that is rotatable around a rotation axis parallel to the rotation axis C1 of the polishing plate 12 and movable in a direction of the rotation axis C1 and in a radial direction of the polishing plate 12, and an abrasive-body adjustment tool (dresser or conditioner) such as a diamond wheel (not shown) that is attached to a lower surface of the adjustment-tool holding member, i.e., a surface of the adjustment-tool holding member opposed to the polishing pad 18, as needed. This adjustment-tool holding member and the abrasive-body adjustment tool attached thereto are pressed against the polishing pad 18 while being rotated and driven by an adjustment tool driving motor (not shown), and are moved back and forth in the radial direction of the polishing plate 12, thereby adjusting a polishing surface of the polishing pad 18 and constantly maintaining a surface condition of the polishing pad 18 in a state suitable for polishing.

As shown in FIG. 2, in a position deviated from the rotation axis C1 on the polishing plate 12, an outer circumferential surface of the short-cylindrical shaped holding disc 20, which holds the workpiece 16 to be polished on its lower surface by suction, adhesion or a holding frame, is supported by a pair of guide rollers 30, 32 (i.e., an idle guide rollers 30 and a drive guide rollers 32) provided on a guide-roller holder base 28, which is fixed in a position fixed to a frame (not shown), such that the holding disc 20 is rotatable around a rotation axis C2. The holding disc 20 is rotated around the rotation axis C2 by a rotational force based on a difference in a peripheral speed of the polishing plate 12 or polishing pad 18, while the holding disc 20 is pressed against the polishing pad 18 on the polishing plate 12 by the load of, for example, a weight 34, so that the workpiece 16 is polished.

The following polishing method is applied when polishing with the polishing machine 10. That is, the polishing plate 12 and the polishing pad 18 attached thereto are rotated around the rotation axis C1 by the plate drive motor 14, the holding disc 20 and the workpiece (silicon wafer) 16 held on the lower surface thereof are rotated around the rotation axis C2 by the drive guide roller 32, the polishing fluid PF that does not contain polishing abrasive grains is supplied onto the surface of the polishing pad 18 from the dripping nozzle 22, and the workpiece 16 held on the holding disc 20 is pressed against the polishing pad 18. As a result, a polished surface of the workpiece 16, i.e., a surface of the workpiece 16 opposed to the polishing pad 18, is polished flat by a chemical polishing action of the polishing fluid PF.

The polishing pad 18 is molded into a sheet from a dense resin that does not contain air bubbles or abrasive grains, a porous resin that has independent pores or communication pores, or an abrasive-grain containing resin that contains abrasive grains (silica) in the independent pores or communication pores. Any one of these resins is a polymer containing carbon C and at least one of hydrogen H, oxygen O, nitrogen N, sulfur S and fluorine F, and has a polishing-rate contribution degree PRN expressed by formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), wherein the polishing-rate contribution degree PRN satisfies formula (2), and preferably satisfies formular (3).

$$PRN = - 5738 {M}_{H} + 84 9.6 {M}_{C} + 1766 {M}_{O} - 40.7 {M}_{N} - 39 4.9 {M}_{S} + 219.4 {M}_{F} \qquad ( 1 )$$

$$268.4 ≦ PRN ≦ 1516.3 \qquad ( 2 )$$

$$268.4 ≦ PRN ≦ 959. 3 \qquad ( 3 )$$

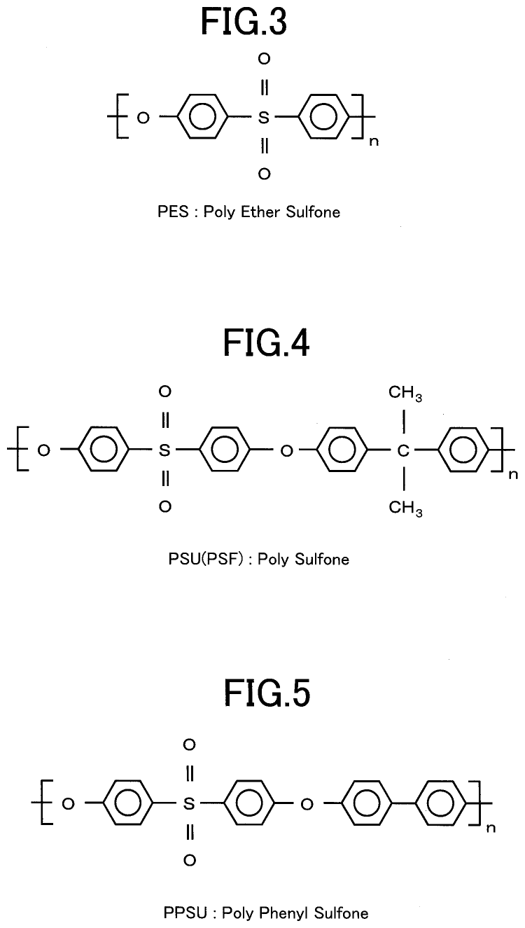

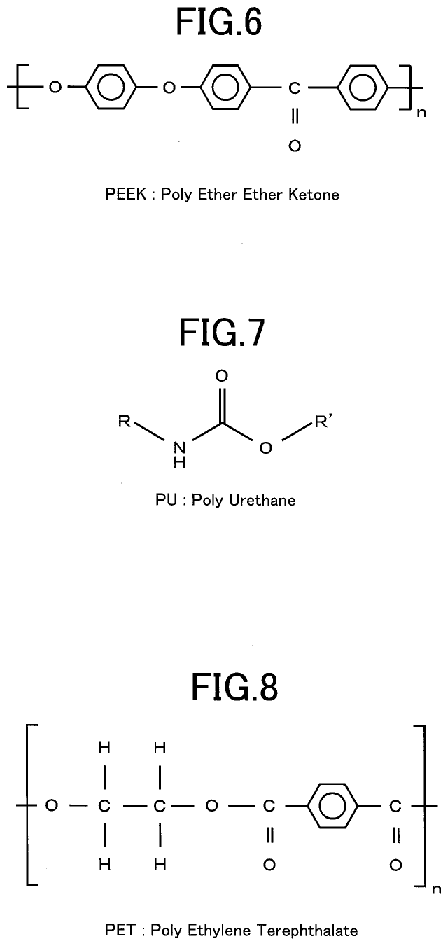

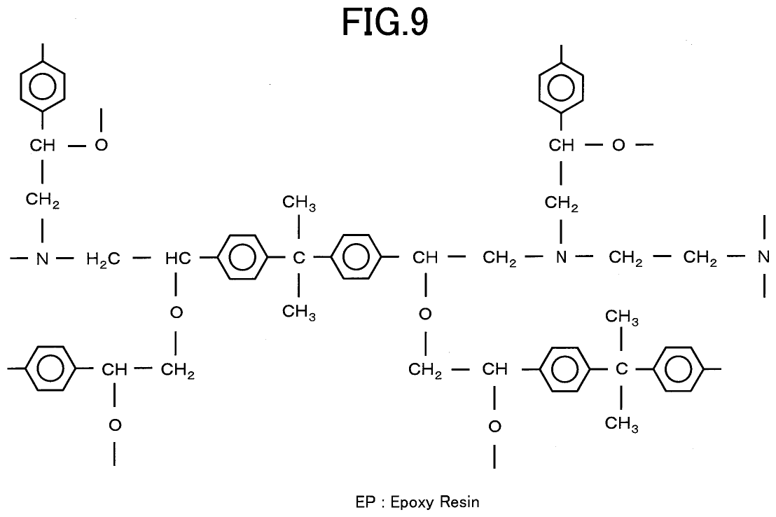

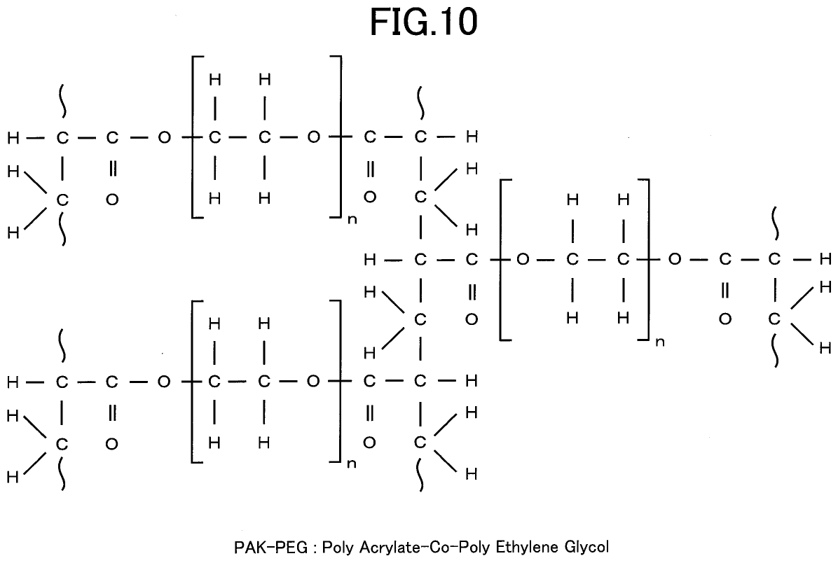

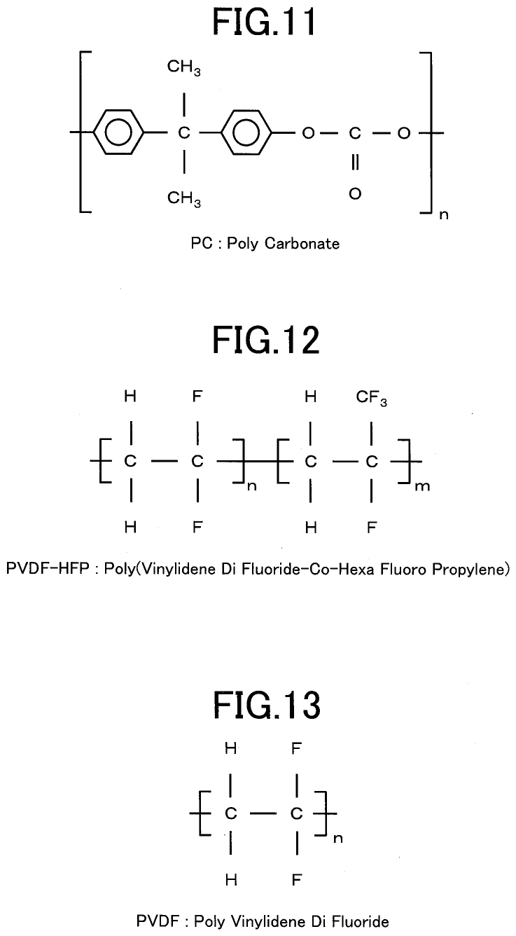

As the resin whose polishing-rate contribution degree PRN satisfies formula (3), there are listed: PES resin (polyethersulfone resin) represented by a chemical structural formula in FIG. 3; PSU resin (polysulfone resin) represented by a chemical structural formula in FIG. 4; PPSU resin (polyphenylsulfone resin) represented by a chemical structural formula in FIG. 5; PEEK resin (polyetheretherketone resin) represented by the chemical structural formula in FIG. 6; PU resin (polyurethane resin synthesized from isocyanate and polyol) represented by a chemical structural formula in FIG. 7; PET resin (polyethylene terephthalate (polyester) resin) represented by a chemical structural formula in FIG. 8; EP resin (cured product of epoxy resin, made of glycidyl ether type epoxy and amine curing agent) represented by a chemical structural formula in FIG. 9; PEG #400 acrylic resin (acrylic resin cured by UV curing of acrylate monomer with acrylic groups bonded to both ends of polyethylene glycol with average molecular weight of 400) represented by a chemical structural formula in FIG. 10; PC resin (polycarbonate resin) represented by a chemical structural formula shown in FIG. 11; copolymer resin of 80% polyvinylidene fluoride and 20% hexafluoropropylene (PVDF (80%)-HFP (20%) resin) represented by a chemical structural formula shown in FIG. 12; and PVDF (100%) resin (polyvinylidene fluoride resin) represented by a chemical structural formula shown in FIG. 13.

### Experimental Example 1

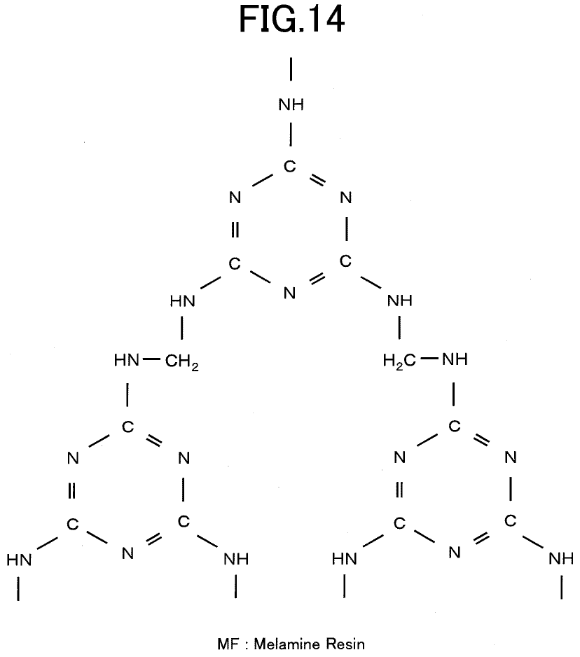

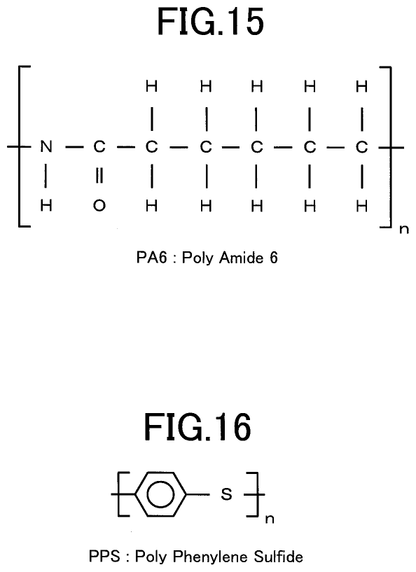

There will be described experimental examples of polishing a semiconductor wafer conducted by the present inventors. First, using an apparatus similar to the polishing machine 10 shown in FIG. 1, a total of 14 types of polishing operations were performed on a SiC wafer having a diameter of 4 inches under the following polishing test condition 1 using comparative examples 1-3 that are polishing pads constituted by resins represented by chemical structural formulas shown in FIGS. 14-16 and examples 1-11 that are polishing pads constituted by resins represented by chemical structural formulas shown in FIGS. 4-13. Each of the resins constituting the polishing pads of the comparative examples 1-3 and the examples 1-11 does not have abrasive grains or pores. A polishing rate PR and a surface roughness Sa of the SiC wafer after the polishing test were measured by using the following polishing rate measurement method and surface roughness measurement method. Further, the polishing-rate contribution degree (PRN) of each of the polishing pads of the comparative example 1-3 and example 1-11 was also measured by using the formula (1).

### [Polishing Test Condition 1]

Workpiece: 4-inch diameter SiC wafer (0001) surface, inclination angle 4°
Workpiece rotation speed: 60 rpm
Polishing pad diameter: 300 mm
Polishing pad rotation speed: 60 rpm
Polishing pressure: 42 kPa
Polishing fluid: KMnO₄ (0.25 mol/l) pH=3.2
Polishing fluid flow rate: 10 ml/min

### [Method of Measuring Polishing Rate]

A difference in mass of the workpiece before and after the polishing test was measured by using an analytical balance, and an amount of polishing (abrasion thickness) was calculated from a known density of the workpiece and a surface area of the polished surface. The polishing rate PR (nm/h) was calculated by dividing the amount of polishing by a polishing time.

### [Method of Measuring Surface Roughness]

The surface roughness of the polished surface of the silicon wafer after the polishing test was measured by using a white-light interference microscope (Hitachi High-Tech Corporation VS-1330), and an arithmetic mean roughness Sa defined in ISO25178 was calculated.

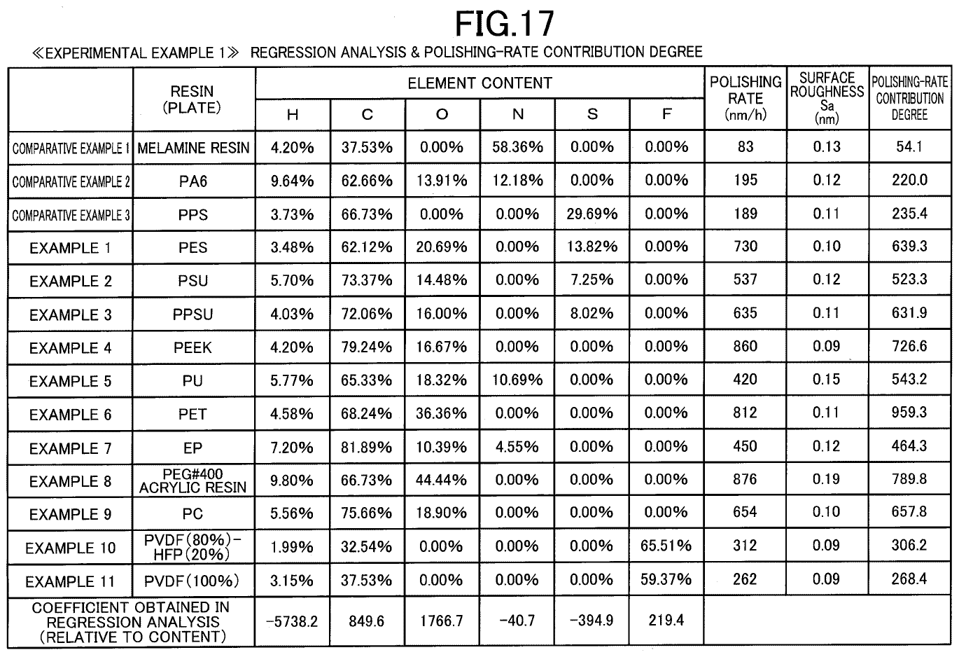

FIG. 17 shows types of the resins constituting three types of polishing pads of the comparative examples 1-3 and eleven types of polishing pads of the examples 1-11, contents of respective elements contained in each of the resins, and the polishing-rate contribution degree PRN of each of the resins, and also polishing test results (polishing rate PR (nm/h) and surface roughness Sa (nm) of the polished surface) in each of the polishing pads in Experimental Example 1.

In FIG. 17, the polishing pads of the comparative examples 1-3 are a group of polishing pads that are relatively poor in practicality with the polishing rate PR being lower than 249 (nm/min) as a criteria value for practicality, while the polishing pads of the examples 1-11 are a group of polishing pads that are acceptable for practical use with the polishing rate PR being higher than 250 (nm/min) as the criteria value for practicality. There is not much difference in the average surface roughness Sa (nm) between the polishing pads of the comparative examples 1-3 and the polishing pads of the examples 1-11. The criteria value of the polishing rate PR for practicality is set to a value three times as high as the polishing rate PR of the melamine resin polishing pad.

### (Derivation of Formula (1) for Polishing-Rate Contribution Degree PRN)

In FIG. 17, the polishing rate PR of the PET resin in the example 6 is about twice as high as that of the PU resin in the example 5, since a bond between nitrogen N and hydrogen H is replaced by a bond between carbon C and oxygen O. The polishing rate PR of the PPS resin in the comparative example 3 is about one-quarter as low as that of the PES resin in the example 1, since oxygen O is absent. The polishing rate PR of the PEEK resin in the example 4 is about 1.2 as high as that of the PES resin in the example 1, since sulfur S is absent. The polishing rate PR of the PEG #400 acrylic resin in the example 8 is about 1.2 as high as that of the PES resin in the example 1, since sulfur S is absent. From these facts, it is assumed that atoms of carbon C and oxygen O have effect of increasing the polishing rate PR, and that atoms of sulfur S, nitrogen N and hydrogen H have effect of increasing the polishing rate PR.

The coefficients (relative to contents) obtained in the regression analysis in FIG. 17 are coefficients of regression equation obtained by making the regression analysis on carbon C, hydrogen H, oxygen O, nitrogen N, sulfur S and fluorine F contained in the comparative examples 1-3 and examples 1-11. The H, N, and S atoms, which have negative coefficients, have the effect of reducing the polishing rate PR, while the C, O, and F atoms, which have positive coefficients, have the effect of increasing the polishing rate PR. It was also made clear that positive and negative of the coefficients of the C, H, O, N, S and F atoms correspond to oxidizing and reducing properties of these atoms. The polishing-rate contribution degree PRN is expressed by the above-described formula (1) in which the coefficient of each element obtained by the regression analysis is applied to the content of the element. In the formula (1), the content of the hydrogen is M_{H} (mass fraction), the content of the carbon is M_{C} (mass fraction), the content of the oxygen is M_{O} (mass fraction), the content of the nitrogen is M_{N} (mass fraction), a content of the sulfur is M_{S} (mass fraction) and the content of the fluorine is M_{F} (mass fraction).

### (Derivation of Range of Polishing-Rate Contribution Degree PRN)

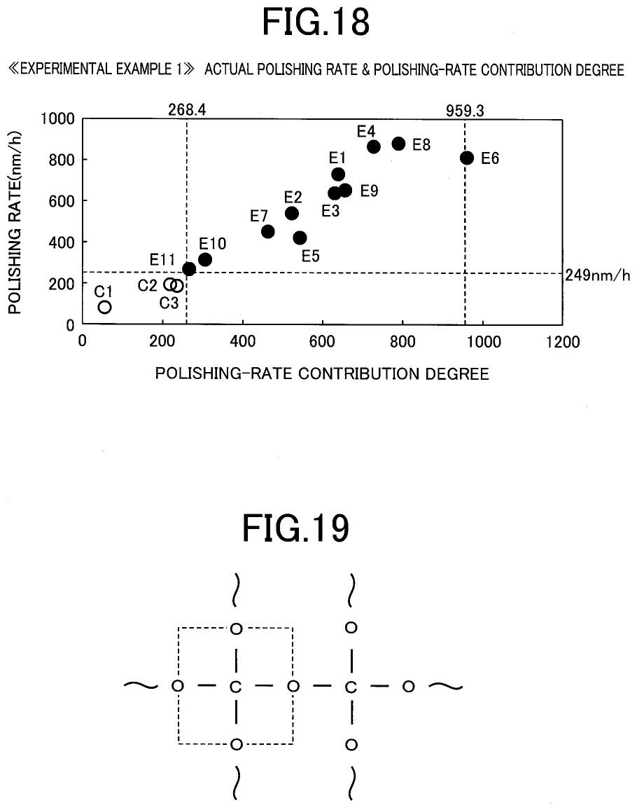

The polishing-rate contribution degree PRN for each of the comparative examples 1-3 and examples 1-11, which is shown in FIG. 17, is calculated by using the above-described formula (1). A relationship between the polishing-rate contribution degree PRN and the polishing rate PR (nm/h) for each of the comparative examples 1-3 and examples 1-11 is shown in FIG. 18. As shown in FIG. 18, a lowest value and a highest value of the minimum polishing-rate contribution degrees PRN for the examples 1-11 are 268 and 959.3, respectively. This leads to the above-described formula (3).

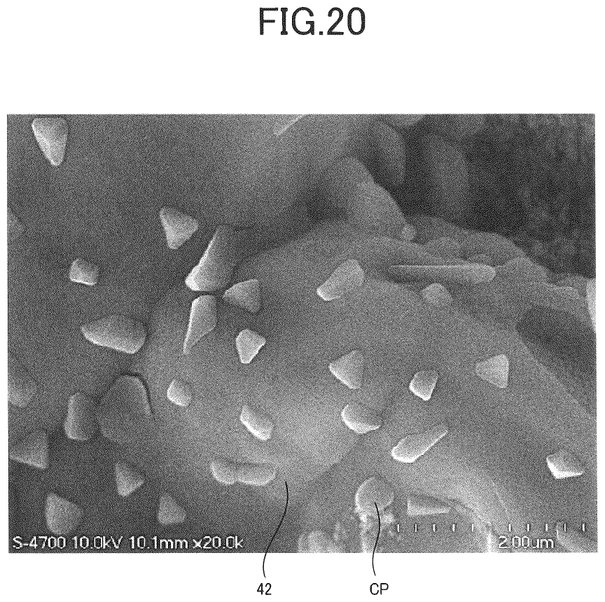

By the way, among the coefficients of carbon C, hydrogen H, oxygen O, nitrogen N, sulfur S and fluorine F contained in the examples 1-11, the element that contributes most to the polishing-rate contribution degree PRN is oxygen O, as shown in the above-described formula (1). Also, for the resin constituting the polishing pad, carbon C is essential as a backbone of the polymer structure. Therefore, based on these facts, theoretically, it is considered that a molecular structure with only carbon C and oxygen O and with the highest amount of oxygen O can provide a maximum value of the polishing-rate contribution degree PRN. Such a resin is the polymer structure shown in FIG. 19. In this polymer, a molar ratio of carbon C to oxygen O is 1:2, since an atomic weight of carbon C is 12.01 and an atomic weight of oxygen O is 15.99. Further, a mass ratio of carbon C to oxygen O is 0.273:0.727.

Thus, since the mass ratio of carbon C to oxygen O is 0.273:0.727, “1516.3” as the theoretical maximum value of the polishing-rate contribution degree PRN can be obtained, by substituting the hydrogen H content MH=0, carbon C content MC=0.273, oxygen O content MO=0.727, nitrogen N content MN=0, sulfur S content MS=0 and fluorine F content MF=0, into a right-hand side of the above-described equation (1). This leads to the above-described formula (2).

### (Explanation of Polishing Mechanism)

Next, there will be explained a polishing mechanism that enables polishing without using abrasive grains in the polishing operation for SiC wafer by using the comparative examples 1-3 and examples 1-11, which are constituted by resin plates containing no abrasive grain and no pore. When a potassium permanganate solution that constitutes the polishing fluid comes into contact with a resin, which has a strong oxidizing power due to inclusion of C atoms, O atoms and/or F atoms therein, it is difficult to take electrons from the resin, so that oxidation reaction shown in formulas (4) and (5) is unlikely to occur. In this situation, evaporation of water caused by heat during polishing precipitates potassium permanganate KMnO₄, which is a tiny crystal that functions as an abrasive. At this time, the precipitated potassium permanganate KMnO₄ as the abrasive has a high electron stripping property as shown in the formulas (4) and (5), so as to have a high oxidizing power and a high polishing rate. On the other hand, when the potassium permanganate solution that constitutes the polishing fluid comes into contact with resin, which is highly reducing due to the presence of H, N and S atoms, KMnO₄ (MnO₄⁻ ion) is reduced by the oxidation-reduction reaction shown in formula (4) or (5), thereby causing the dissolution of Mn²⁺ ions or the precipitation of MnO₂. If Mn²⁺ ions are eluted at this time, there is no solid material to serve as abrasive grains, so polishing is not possible or the polishing rate is very low. If MnO₂ precipitates, its electron stripping ability is low as shown in formula (6), so that its oxidizing power is low, thereby resulting in a low polishing rate.

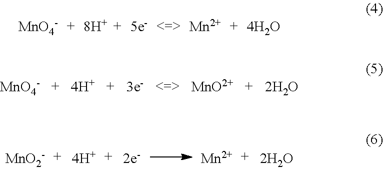

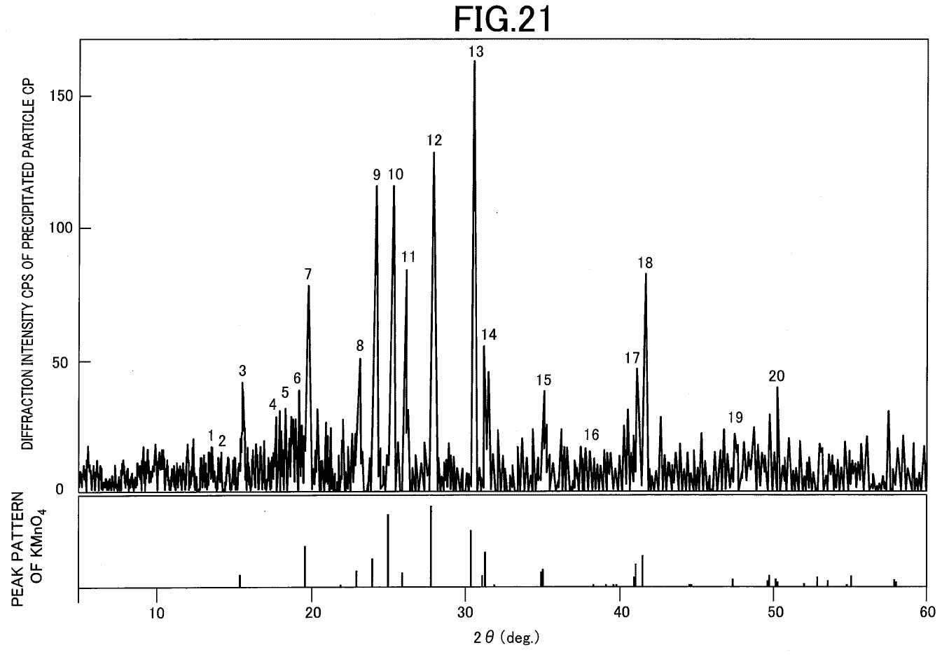

FIG. 20 shows an SEM photograph of minute precipitates (KMnO₄ crystals) CP contained in a paste-like material on the surface of a polishing pad constituted by a resin with strong oxidizing power due to the above-mentioned C atoms, O atoms and/or F atoms, i.e., any of the resins in the examples 1-11, which come into contact with the potassium permanganate solution that constitutes the polishing fluid. FIG. 21 shows an X-ray diffraction spectrum of the precipitates CP. In FIG. 21, the X-ray diffraction spectrum of the precipitates CP matches the peak pattern of KMnO₄, so it is clear that the precipitates CP are KMnO₄ precipitates. Since the KMnO₄ precipitates CP function as abrasive grains, SiC wafers can be polished by using even the polishing pad constituted by a resin plate that does not contain abrasive grains or pores.

### Experimental Example 2

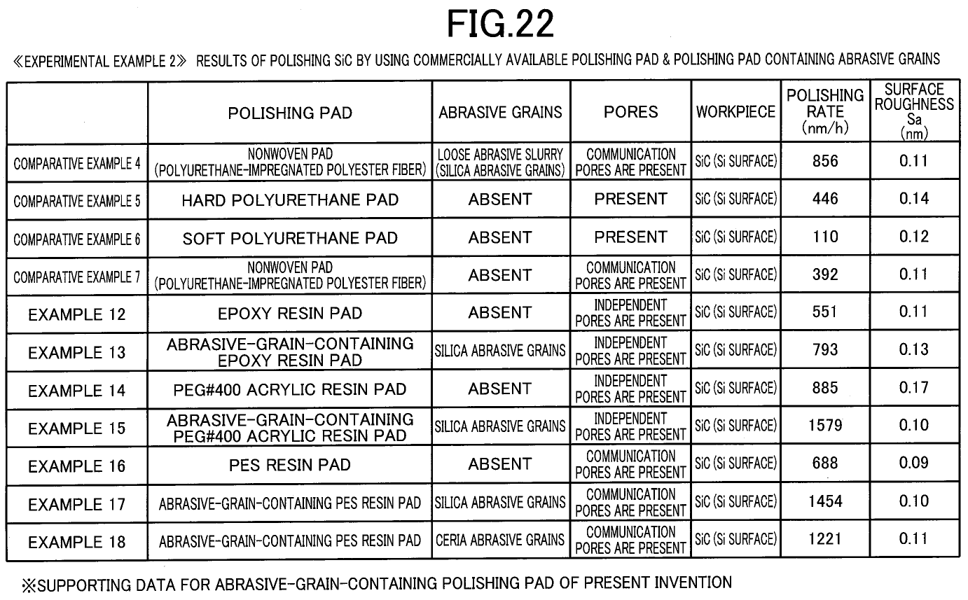

Next, polishing pads of comparative examples 4-7 and examples 12-18 shown in FIG. 22 were used in an apparatus constructed similarly as the polishing machine 10 shown in FIG. 1, and a SiC wafer having a diameter of 4 inches was polished under a polishing test condition 2 that is the same as the polishing test conditions 1. The Experimental Example 2 is different from the Experimental Example 1 in that a commercially available polishing pad and a polishing pad containing abrasive grains are used, a loose abrasive slurry containing silica abrasive grains is used in the comparative example 4, and abrasive-containing polishing pads are used in the examples 13, 15, 17 and 18. As described above, any one of the resins constituting the polishing pads of the examples 12-18 is a resin whose polishing-rate contribution degree PRN satisfies the above-described formula (3).

As shown in FIG. 22, the comparative examples 4 and 7 have in common that they are nonwoven pads (polyurethane-impregnated polyester fibers), but the polishing rate PR of the comparative example 4 is more than twice as high as that of the comparative example 7. This is considered to be owing to the use of the loose abrasive slurry. Further, the examples 12-18 provide a higher polishing rate PR than the comparative example 5.

As shown in FIG. 22, the examples 12 and 13 have in common that they use epoxy resin pads, but the abrasive-grain-containing resin pad used in the example 13 contains silica abrasive grains, and the example 13 provides the polishing rate PR that is about 1.4 times as high as that provided by the example 12. Similarly, the examples 14 and 15 have in common that they use PEG #400 acrylic resin, but the abrasive-grain-containing resin pad used in the example 15 contains silica abrasive grains, and the example 15 provides the polishing rate PR that is about 1.8 times as high as that provided by the example 14. Further, the examples 16 and 17 have in common that they use PES resin pads, but the abrasive-grain-containing resin pad used in the example 17 contains silica abrasive grains, and the example 17 provides the polishing rate PR that is about 2.1 times as high as that provided by the example 16. Further, the example 18 and 17 have in common that they use abrasive-grain-containing resin pad, but the example 18 is different from the example 17 in that the abrasive grains contained in the resin pad are ceria abrasive grains. The example 18 provides the polishing rate PR which is relatively high and which is about 0.84 times as high as that provided by the example 17 that uses the abrasive-grain-containing resin pad containing silica abrasive grains.

FIG. 23 is a view schematically showing a structure of the above-described abrasive-containing polishing pad. In FIG. 23, a base material resin 42 of the abrasive-containing polishing pad LHA is fibrous having an average cross-sectional diameter of, for example, about 0.05 (μm), and polishing abrasive grains 44 having an average grain size of, for example, 0.3 (μm) are present in gaps in the fibrous base material resin 42, while being partially attached to an outer periphery of the base material resin 42 or separated from the base material resin 42 in the gaps. Considering communication pores 46 that connect the gaps in the fibrous base material resin 42, it can be considered that the polishing abrasive grains 44 are provided within the communication pores 46. The communication pores 46 are formed to communicate with vertically elongated pores (not shown) and to communicate with each other. That is, the polishing abrasive grains 44 are present in a state in which some of the abrasive grains 44 are fixed to inner walls of the communication pores 46, or in a state in which some of the abrasive grains 44 are separated from the base material resin 42 within the communication pores 46, and each of the communication pores 46 contains at least one of the polishing abrasive grains 44 and is formed in the base material resin 42. In a polishing operation with use of this abrasive-containing polishing pad LHA, the polishing abrasive grains 44 contained in the abrasive-containing polishing pad LHA are supplied to the polishing surface, whereby the polishing rate PR is increased.

### (Explanation of Polishing Mechanism of Abrasive-Containing Polishing Pad)

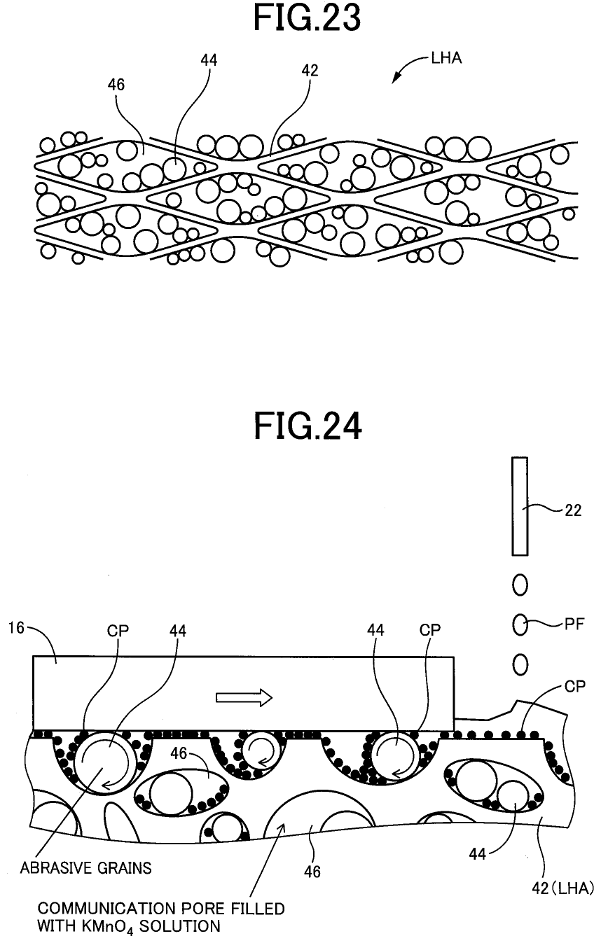

FIG. 24 is a view schematically showing the polishing mechanism of the abrasive-containing polishing pad LHA. As shown in FIG. 24, the polishing fluid PF is dripped onto a surface of the abrasive-containing polishing pad LHA, and the communication pores 46 is filled with the polishing fluid PF. As a result, the potassium permanganate solution constituting the polishing fluid PF comes into contact with the base material resin 42 that has a strong oxidizing power due to the inclusion of C atoms, O atoms and/or F atoms, and electrons are taken away by oxidation reaction shown in the above-described formula (4) or (5), and minute precipitates (KMnO₄ crystals) CP that function as abrasive grains are precipitated.

In this state, when the workpiece 16 is moved on the surface of the abrasive-containing polishing pad LHA, the precipitates (KMnO₄ crystals) CP and the polishing abrasive grains 44 are in contact with the workpiece 16, and a frequency of contact of the precipitates CP with the workpiece 16 is increased by movement of the polishing abrasive grains 44 whereby a high polishing rate PR is obtained.

### Experimental Example 3

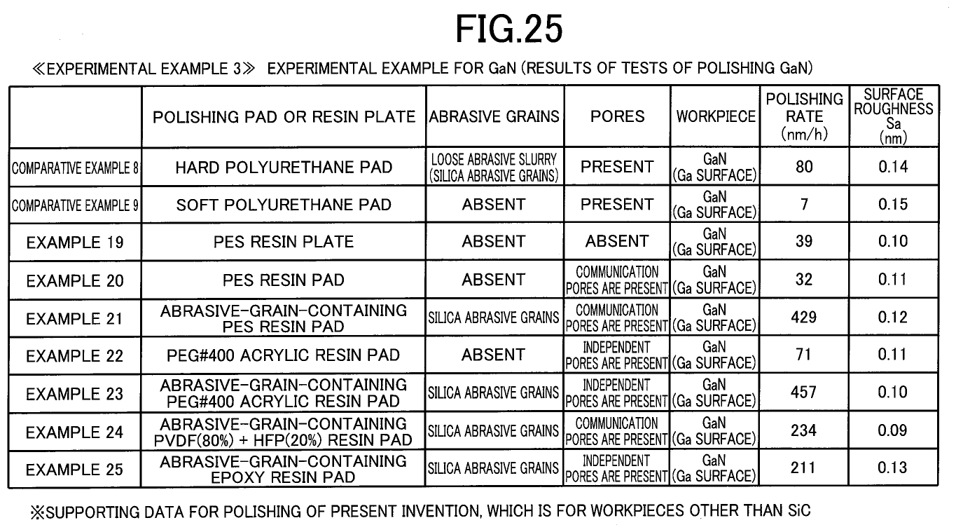

Next, polishing pads of comparative examples 8-9 and examples 19-25 shown in FIG. 25 were used in an apparatus constructed similarly as the polishing machine 10 shown in FIG. 1, and a GaN wafer having a diameter of 2 inches was polished under a polishing test condition 3. The Experimental Example 3 is different from the Experimental Example 1 in that the GaN wafer is polished, a loose abrasive slurry containing silica abrasive grains is used in comparative example 8, and abrasive-containing polishing pads are used in examples 21, 23, 24 and 25. As described above, any one of the resins constituting the polishing pads of the examples 19-258 is a resin whose polishing-rate contribution degree PRN satisfies the above-described formula (3).

### [Polishing Test Condition 3]

Workpiece: 2-inch diameter GaN wafer (0001) Ga surface
Workpiece rotation speed: 60 rpm
Polishing pad diameter: 300 mm
Polishing pad rotation speed: 60 rpm
Polishing pressure: 50 kPa
Polishing fluid: KMnO₄ (0.25 mol/l) pH=1.0
Polishing slurry: KMnO₄ (0.25 mol/l) pH=1.0+silica (12.5 wt %)
Polishing fluid flow rate: 10 ml/min

As shown in FIG. 25, the comparative examples 8 and 9 have in common that they are polyurethane resin pads (with pores), but the polishing rate PR of the comparative example 8 is more than ten times as high as that of the comparative example 9. This is considered to be owing to the use of the loose abrasive slurry. Further, the examples 19-25 provide a higher polishing rate PR than the comparative example 9.

As shown in FIG. 25, the examples 19, 20 and 21 have in common that they use PES resin pads, but are different in that the example 19 uses a resin plate having no pore, the example 20 uses a resin pad having communication pores and the example 21 uses an abrasive-containing polishing pad containing silica abrasive grains. The polishing rate PR of the example 21 is about ten times as high as those of the examples 19 and 20. The examples 22 and 23 have in common that they use PEG #400 resin pads, but are different in that the example 22 uses a resin pad having independent pores and the example 23 uses an abrasive-containing polishing pad containing silica abrasive grains. The polishing rate PR of the example 23 is about 6.5 times as high as that of the example 22. The example 24 is different from the comparative example 9 in that the example 24 uses a silica-abrasive-containing polishing pad of PVDF (80%)+HFP (20%) resin and the polishing rate PR of the example 24 is about 33 times as high as that of the comparative example 9. The examples 25 is different from the comparative examples 9 in that the example 25 uses a silica-abrasive-containing polishing pad of epoxy resin and the polishing rate PR of the example 25 is about 30 times as high as that of the comparative example 9.

### Experimental Example 4

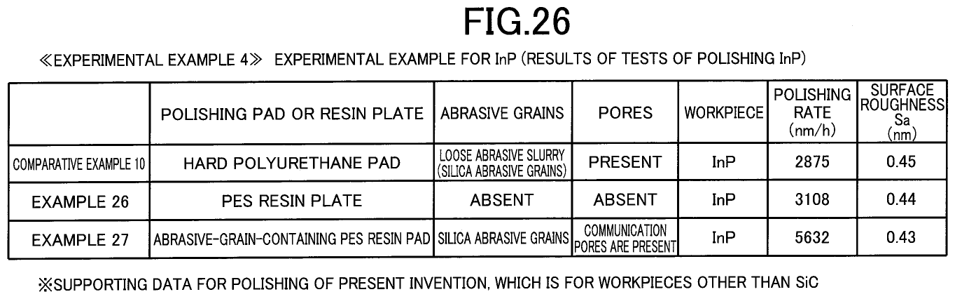

Next, polishing pads of comparative example 10 and examples 26 and 27 shown in FIG. 26 were used in an apparatus constructed similarly as the polishing machine 10 shown in FIG. 1, and an InP wafer having a diameter of 2 inches was polished under a polishing test condition 4. The Experimental Example 4 is different from the Experimental Example 1 in that the InP wafer is polished, a loose abrasive slurry containing silica abrasive grains is used in the comparative example 10, and an abrasive-containing polishing pad is used in the example 27. As described above, any one of the resins constituting the polishing pads of the examples 26 and 27 is a resin whose polishing-rate contribution degree PRN satisfies the above-described formula (3).

### [Polishing Test Condition 4]

Workpiece: 2-inch diameter InP wafer (100)
Workpiece rotation speed: 90 rpm
Polishing pad diameter: 300 mm
Polishing pad rotation speed: 90 rpm
Polishing pressure: 14 kPa
Polishing fluid KMnO₄ (0.25 mol/l) pH=6.9
Polishing slurry: KMnO₄ (0.25 mol/l) pH=6.7+silica (12.5 wt %)
Polishing fluid flow rate: 10 ml/min

As shown in FIG. 26, the comparative example 10 uses a hard polyurethane resin pad (with pores) together with loose abrasive slurry, and provides a relatively high polishing rate PR. The example 26 uses a PES resin plate that does not have pores or abrasive grains, and provides a polishing rate PR that is about 8% higher than comparative example 10. The example 27 uses an abrasive-containing PES resin pad that has communication pores and contains silica abrasive grains within the communication pores, and provides a polishing rate PR that is about twice as high as the comparative example 10.

As described above, in the polishing pad 18 of the present embodiment constituted by the rein and in the polishing method of the present embodiment using the polishing pad 18, the polishing fluid PF that is the strong oxidizing agent solution containing no abrasive grain, so that a fine-mesh filter can be used in a circulation path for circulating the polishing fluid PF, thereby making it possible to significantly reduce occurrence of scratches and to provide stable polishing of the semiconductor wafer, while suppressing consumption of the abrasive grains and reducing an environmental burden. In addition, the resin polishing pad is the polymer that contains the carbon and at least one of the hydrogen, oxygen, nitrogen, sulfur and fluorine, and the polishing-rate contribution degree PRN of the polishing pad is not lower than 268.4 and is not higher than 1516.3, so that the polishing rate is significantly improved.

Further, in the polishing pad 18 of the present embodiment constituted by the rein and in the polishing method of the present embodiment using the polishing pad 18, the polishing-rate contribution degree PRN of the polishing pad satisfies the above-described formula (3), so that the polishing-rate contribution degree PRN is not lower than 268.4 and is not higher than 959.3, whereby the polishing rate is further improved.

Further, in the polishing pad 18 of the present embodiment constituted by the rein and in the polishing method of the present embodiment using the polishing pad 18, the polishing fluid PF contains the potassium permanganate solution as the strong oxidizing agent solution. Thus, a reduction of potassium permanganate ions contained in the potassium permanganate solution is suppressed by the polymer constituting the polishing pad 18, thereby causing permanganate to precipitate on the polishing pad 18, and precipitated particles CP of the permanganate are used as the abrasive particles to polish the workpiece (semiconductor wafer) 16.

Further, in the polishing pad 18 of the present embodiment constituted by the rein and in the polishing method of the present embodiment using the polishing pad 18, the resin constituting the polishing pad is one of PES (polyether sulfone) resin, PSU (polysulfone) resin, PPSU (polyphenyl sulfone) resin, PEEK (polyether ether ketone) resin, PU (polyurethane) resin, PET (polyethylene terephthalate (polyester)) resin, EP (epoxy) resin cured product (cured product of glycidyl ether type epoxy and amine hardener), PEG #400 acrylic resin (acrylic resin made by UV hardening an acrylate monomer in which acrylic groups are bonded to both ends of polyethylene glycol with an average molecular weight of 400), PC (polycarbonate) resin, PVDF80%+HFP20% (copolymer resin made of 80% polyvinylidene fluoride and 20% hexafluoropropylene) and PVDF100% (polyvinylidene fluoride resin). Thus, when the polishing fluid PF containing metal ions comes into contact with the polishing pad 18, metal oxide particles are deposited on the polishing pad 18.

Further, in the polishing pad 18 of the present embodiment constituted by the rein and in the polishing method of the present embodiment using the polishing pad 18, the polishing pad 18 may have no abrasive grain and no independent pore or no communication pore, or may have the abrasive grains, independent pores and/or communication pores. Further, preferably, the polishing pad 18 may contain silica abrasive grains, alumina abrasive grains, zirconia abrasive grains, manganese oxide abrasive grains and/or ceria abrasive grains as the abrasive grains in the independent pores and/or communication pores. Thus, it is easier to polish the semiconductor wafer to a flat surface owing to ubiquitous distribution of the abrasive grains, and to increases the number of points of action, thereby resulting in a high polishing rate.

Further, in the polishing pad 18 of the present embodiment constituted by the rein and in the polishing method of the present embodiment using the polishing pad 18, the polishing method of polishing the semiconductor wafer by using the polishing fluid PF that is the strong oxidizing agent solution containing no abrasive grain, and the polishing pad 18 made of the resin is practiced. The polishing pad is made of the polymer containing carbon C and at least one of hydrogen H, oxygen O, nitrogen N, sulfur S and fluorine F, and having the polishing-rate contribution degree PRN expressed by the above-described formula (1) where the content of the hydrogen is M_{H} (mass fraction), the content of the carbon is M_{C} (mass fraction), the content of the oxygen is M_{O} (mass fraction), the content of the nitrogen is M_{N} (mass fraction), the content of the sulfur is M_{S} (mass fraction) and the content of the fluorine is M_{F} (mass fraction), such that the polishing-rate contribution degree PRN satisfies the above-described formula (2).

Thus, the polishing fluid PF that is the strong oxidizing agent solution containing no abrasive grains is used, so that a fine-mesh filter can be used in a circulation path for circulating the polishing fluid PF, thereby making it possible to significantly reduce occurrence of scratches and to provide stable polishing of the semiconductor wafer, while suppressing consumption of the abrasive grains 44 and reducing an environmental burden. In addition, the resin polishing pad 18 is the polymer that contains the carbon and at least one of the hydrogen, oxygen, nitrogen, sulfur and fluorine, and the polishing-rate contribution degree PRN of the polishing pad is not lower than 268.4 and is not higher than 1516.3, so that the polishing rate is significantly improved.

While the preferred embodiment of the present invention has been described above in detail by reference to the drawings, it is to be understood that the present invention is not limited to the above-described embodiment and that the invention may be otherwise embodied.

For example, in the above-described embodiment, the polishing pad 18 is called LHA pad (registered trademark), and the base material resin 42 is fibrous. However, this is merely a preferred embodiment of the present invention, and the base material resin 42 in the polishing pad 18 of the present invention may be constituted by a dense resin having no pore and no abrasive grain, as long as the resin contains at least one of carbon C, hydrogen H, oxygen O, nitrogen N, sulfur S and fluorine F in each repeating unit.

Further, in the above-described embodiment, the polishing pad 18, particularly, the LHA pad effective for polishing the GaN wafer, is provided with mesh-like communication pores 46, but it may be provided with bubble-like communication pores 46 or may be made of a dense resin without the communication pores 46.

Further, in the above-described embodiment, the polishing fluid PF may contain sodium permanganate ions obtained by dissolving sodium permanganate in water. In this case, when the polishing fluid PF comes into contact with the polishing pad 18, the sodium permanganate precipitates as a permanganate salt on the polishing pad 18.

It should be noted that what has been described above is merely one embodiment, and other examples are not provided, but the present invention can be embodied in various forms with various modifications and improvements based on the knowledge of those skilled in the art without departing from spirit of the present invention.

### DESCRIPTION OF REFERENCE SIGNS

10: polishing machine
16: workpiece (semiconductor wafer)
18: polishing pad
42: base material resin
44: polishing abrasive grain
46: pore
PF: polishing fluid
CP: precipitated particles (abrasive particles) of permanganate

1. A polishing pad for polishing a semiconductor wafer by using a polishing fluid that is a strong oxidizing agent solution containing no abrasive grain,
wherein the polishing pad is made of a polymer containing carbon C and at least one of hydrogen H, oxygen O, nitrogen N, sulfur S and fluorine F, and having a polishing-rate contribution degree PRN expressed by formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), such that the polishing-rate contribution degree PRN satisfies formula (2).
$$PRN = - 5738 {M}_{H} + 84 9.6 {M}_{C} + 1766 {M}_{O} - 40.7 {M}_{N} - 39 4.9 {M}_{S} + 219.4 {M}_{F} \qquad ( 1 )$$
$$268.4 ≦ PRN ≦ 1516.3 \qquad ( 2 )$$

2. The polishing pad according to claim 1, wherein the polishing-rate contribution degree PRN satisfies formula (3).
$$268.4 ≦ PRN ≦ 959. 3 \qquad ( 3 )$$

3. The polishing pad according to claim 1, wherein the polishing fluid contains a potassium permanganate solution as the strong oxidizing agent solution.

4. The polishing pad according to claim 1, wherein a resin constituting the polishing pad is one of PES (polyether sulfone) resin, PSU (polysulfone) resin, PPSU (polyphenyl sulfone) resin, PEEK (polyether ether ketone) resin, PU (polyurethane) resin, PET (polyethylene terephthalate (polyester)) resin, EP (epoxy) resin cured product (cured product of glycidyl ether type epoxy and amine hardener), PEG #400 acrylic resin (acrylic resin made by UV hardening an acrylate monomer in which acrylic groups are bonded to both ends of polyethylene glycol with an average molecular weight of 400), PC (polycarbonate) resin, PVDF80%+HFP20% (copolymer resin made of 80% polyvinylidene fluoride and 20% hexafluoropropylene) and PVDF100% (polyvinylidene fluoride resin).

5. The polishing pad according to claim 1, wherein the polishing pad is constituted by one of a resin having no abrasive grain and no independent pore or no communication pore, a resin having independent pores and/or communication pores and a resin containing silica abrasive grains, alumina abrasive grains, zirconia abrasive grains, manganese oxide abrasive grains and/or ceria abrasive grains as abrasive grains in the independent pores and/or communication pores.

6. A polishing method of polishing a semiconductor wafer by using a polishing fluid that is a strong oxidizing agent solution containing no abrasive grain, and a polishing pad made of a resin,
wherein the polishing pad is made of a polymer containing carbon and at least one of hydrogen, oxygen, nitrogen, sulfur and fluorine, and having a polishing-rate contribution degree PRN expressed by formula (1) where a content of the hydrogen is M_{H} (mass fraction), a content of the carbon is M_{C} (mass fraction), a content of the oxygen is M_{O} (mass fraction), a content of the nitrogen is M_{N} (mass fraction), a content of the sulfur is M_{S} (mass fraction) and a content of the fluorine is M_{F} (mass fraction), such that the polishing-rate contribution degree PRN satisfies formula (2).
$$PRN = - 5738 {M}_{H} + 84 9.6 {M}_{C} + 1766 {M}_{O} - 40.7 {M}_{N} - 39 4.9 {M}_{S} + 219.4 {M}_{F} \qquad ( 1 )$$
$$268.4 ≦ PRN ≦ 1516.3 \qquad ( 2 )$$

7. The polishing method according to claim 6, wherein the polishing-rate contribution degree PRN satisfies formula (3).
$$268.4 ≦ PRN ≦ 959. 3 \qquad ( 3 )$$

8. The polishing method according to claim 6, wherein the polishing fluid contains a potassium permanganate solution as the strong oxidizing agent solution.

9. The polishing method according to claim 6, wherein the resin constituting the polishing pad is one of PES (polyether sulfone) resin, PSU (polysulfone) resin, PPSU (polyphenyl sulfone) resin, PEEK (polyether ether ketone) resin, PU (polyurethane) resin, PET (polyethylene terephthalate (polyester)) resin, EP (epoxy) resin cured product (cured product of glycidyl ether type epoxy and amine hardener), PEG #400 acrylic resin (acrylic resin made by UV hardening an acrylate monomer in which acrylic groups are bonded to both ends of polyethylene glycol with an average molecular weight of 400), PC (polycarbonate) resin, PVDF80%+HFP20% (copolymer resin made of 80% polyvinylidene fluoride and 20% hexafluoropropylene) and PVDF100% (polyvinylidene fluoride resin).

10. The polishing method according to claim 6, wherein the polishing pad is constituted by one of a resin having no abrasive grain and no independent pore or no communication pore, a resin having independent pores and/or communication pores and a resin containing silica abrasive grains, alumina abrasive grains, zirconia abrasive grains, manganese oxide abrasive grains and/or ceria abrasive grains as abrasive grains in the independent pores and/or communication pores.
